(19) United States
(12) Patent Application Publication
(10) Pub. No.: US 2015/0319842 A1
(43) Pub. Date: Nov. 5, 2015

(54) CIRCUIT BOARD AND METHOD FOR MANUFACTURING THE SAME

(71) Applicant: IBIDEN CO., LTD., Ogaki (JP)

(72) Inventors: Koji ASANO, Ogaki (JP); Naoki KATSUDA, Ogaki (JP)

(73) Assignee: IBIDEN CO., LTD., Ogaki (JP)

(21) Appl. No.: 14/700,373

(22) Filed: Apr. 30, 2015

(30) Foreign Application Priority Data
Apr. 30, 2014 (JP) 2014-094149

(51) Int. Cl. H05K 1/02; H05K 3/42; H05K 1/11; H05K 3/00; H05K 3/18

(52) U.S. Cl. CPC H05K 1/0206; H05K 3/0094; H05K 3/0026; H05K 3/188; H05K 3/181; H05K 1/115; H05K 1/0298; H05K 3/429; H05K 3/425; H05K 2201/09545; H05K 2203/072; H05K 2203/0723

(57) ABSTRACT

A circuit substrate includes an insulating layer, circuit layers including a first layer on first surface side of the insulating layer and a second layer on second surface side of the insulating layer, conductor heat transfer layers including a first transfer layer on the first side of the insulating layer and a second transfer layer on the second side of the insulating layer, through hole electrical conductors filling first through holes penetrating through the insulating layer such that the electrical conductors connect the first and second layers, and a through hole thermal conductor filling a second through hole penetrating through the insulating layer such that the thermal conductor connects the first and second transfer layers. The second hole is positioned between two or more of the first holes and has a shape extending in direction that intersects direction connecting the two or more of the first holes.

### CROSS-REFERENCE TO RELATED APPLICATIONS

The present application is based upon and claims the benefit of priority to Japanese Patent Application No. 2014-094149, filed Apr. 30, 2014, the entire contents of which are incorporated herein by reference.

### BACKGROUND OF THE INVENTION

1. Field of the Invention

The present invention relates to a circuit substrate that has a thermal conductor built in for heat dissipation and to a method for manufacturing the circuit substrate.

2. Description of Background Art

As a circuit substrate, a thermal conductor for heat dissipation that is formed in a block shape in advance may be provided by embedding the thermal conductor in an insulating layer. The circuit substrate is used in such a manner that the thermal conductor is arranged directly below a semiconductor chip (for example, see U.S. Patent Application Publication No. 2012/0255165). The entire contents of this publication are incorporated herein by reference.

### SUMMARY OF THE INVENTION

According to one aspect of the present invention, a circuit substrate includes an insulating layer, conductor circuit layers including a first conductor circuit layer formed on a first surface side of the insulating layer and a second conductor circuit layer formed on a second surface side of the insulating layer, conductor heat transfer layers including a first conductor heat transfer layer formed on the first surface side of the insulating layer and a second conductor heat transfer layer formed on the second surface side of the insulating layer, through hole electrical conductors including plating filling first through holes penetrating through the insulating layer such that the through hole electrical conductors are connecting the first and second conductor circuit layers, and a through hole thermal conductor including plating filling a second through hole penetrating through the insulating layer such that the through hole thermal conductor is connecting the first and second conductor heat transfer layers. The second through hole is positioned between two or more of the first through holes and has a shape extending in a direction that intersects a direction connecting the two or more of the first through holes.

According to another aspect of the present invention, a method for manufacturing a circuit substrate includes forming first through holes penetrating through an insulating layer, forming second through hole penetrating through the insulating layer, filling plating in the first through holes such that through hole electrical conductors including the plating is formed through the insulating layer, filing plating in the second through hole such that a through hole thermal conductor including the plating is formed through the insulating layer, forming conductor circuit layers including a first conductor circuit layer on a first surface side of the insulating layer and a second conductor circuit layer on a second surface side of the insulating layer such that the first and second conductor circuit layers are connected by the through hole electrical conductors, and forming conductor heat transfer layers including a first conductor heat transfer layer on the first surface side of the insulating layer and a second conductor heat transfer layer on the second surface side of the insulating layer such that the first and second conductor heat transfer layers are connected by the through hole thermal conductor. The forming of the second through hole includes positioning the second through hole between two or more of the first through holes and forming the second through hole in a shape extending in a direction that intersects a direction connecting the two or more of the first through holes.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a plan view of a circuit substrate according to a first embodiment of the present invention;

FIG. 2 is a plan view of a product region in the circuit substrate;

FIG. 3 is a cross-sectional view of the circuit substrate in an A-A cutting plane of FIG. 2;

FIG. 4 is a plan cross-sectional view of the circuit substrate at a conductor heat transfer layer end surface;

FIG. 5A-5D are cross-sectional views illustrating manufacturing processes of the circuit substrate according to an embodiment of the present invention;

FIG. 6A-6C are cross-sectional views illustrating the manufacturing processes of the circuit substrate;

FIG. 7A-7C are cross-sectional views illustrating the manufacturing processes of the circuit substrate;

FIG. 8A-8C are cross-sectional views illustrating the manufacturing processes of the circuit substrate;

FIG. 9 is a cross-sectional view of a PoP that includes the circuit substrate;

FIG. 10 is a cross-sectional view of a circuit substrate of a second embodiment;

FIGS. 11A and 11B are cross-sectional views illustrating manufacturing processes of the circuit substrate according to an embodiment of the present invention;

FIGS. 12A and 12B are cross-sectional views illustrating the manufacturing processes of the circuit substrate; and

FIG. 13 is a cross-sectional view of a circuit substrate of another embodiment.

### DETAILED DESCRIPTION OF THE EMBODIMENTS

The embodiments will now be described with reference to the accompanying drawings, wherein like reference numerals designate corresponding or identical elements throughout the various drawings.

### First Embodiment

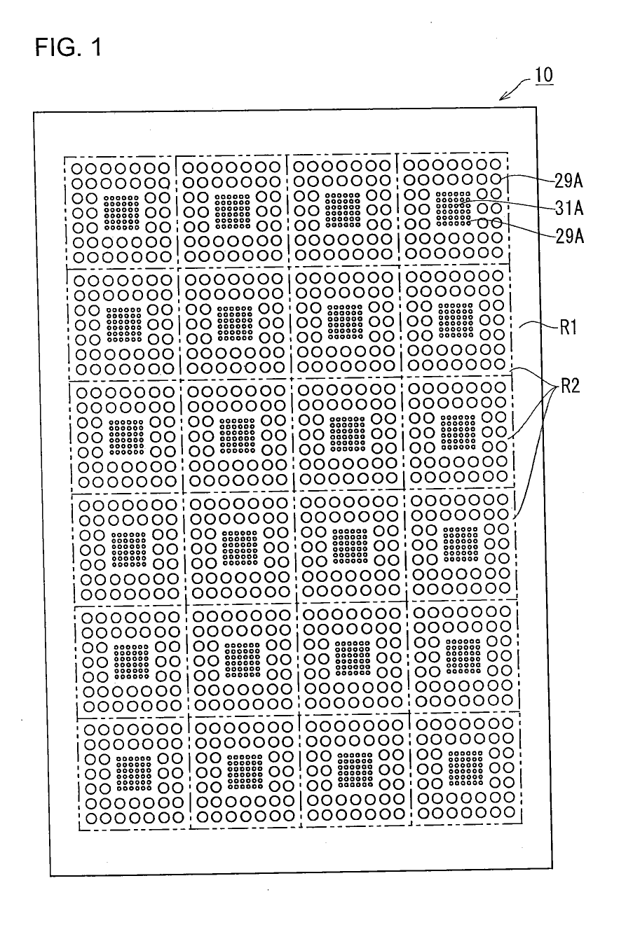

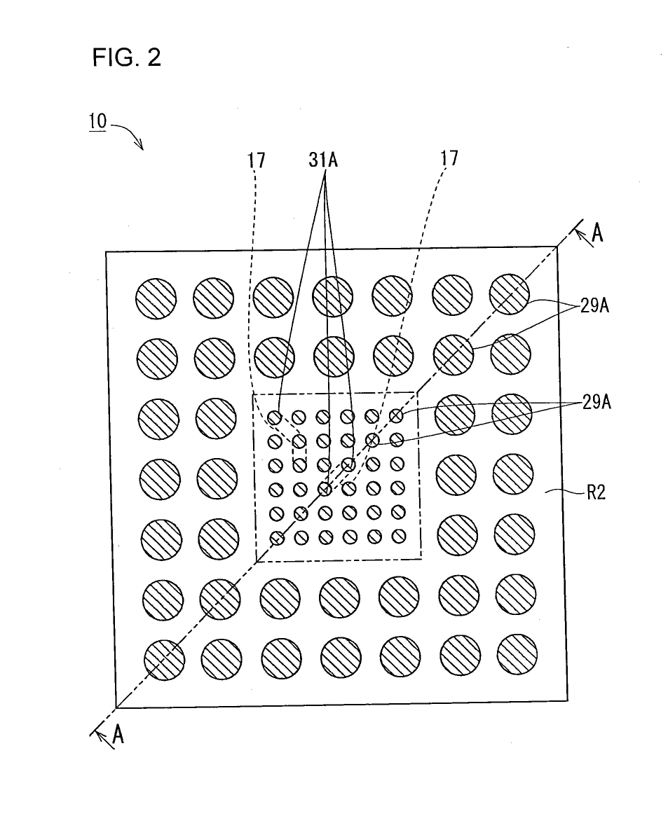

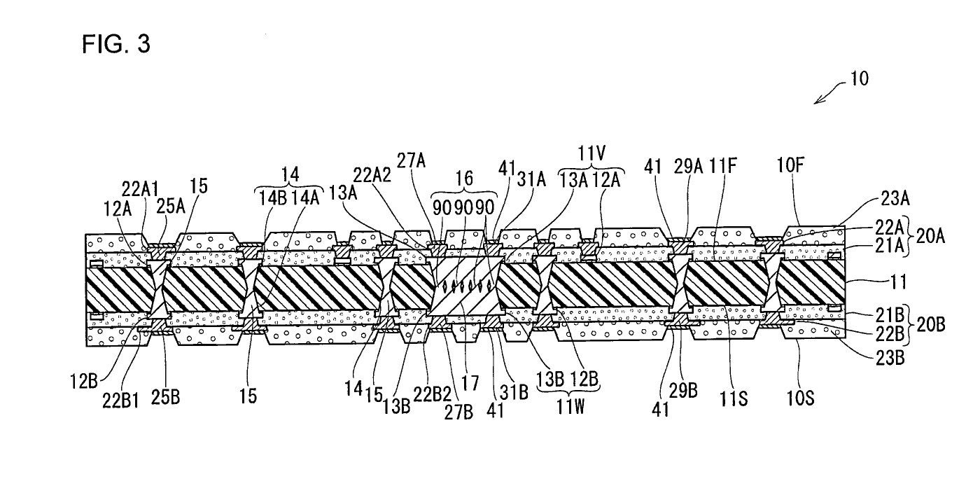

In the following, a first embodiment of the present invention is described based on FIG. 1-9. As illustrated in a plan view of FIG. 1, a circuit substrate 10 of the present embodiment has, for example, a frame-shaped discard region (R1) along an outer edge, and an inner side of the discard region (R1) is divided into multiple square product regions (R2). FIG. 2 illustrates an enlarged view of one product region (R2). FIG. 3 illustrates an enlarged view of a cross-sectional structure of the circuit substrate 10, the cross section being taken by cutting the product region (R2) along a diagonal line.

As illustrated in FIG. 3, the circuit substrate 10 is structured to respectively have build-up layers (20A, 20B) on both front and back sides of a core substrate 11. The core substrate 11 corresponds to an “insulating layer” according to an embodiment of the present invention and is formed by an insulating member. A conductor layer (11V) is formed on an F surface (11F) that is a front surface of the core substrate 11. The conductor layer (11V) includes a conductor circuit layer (12A) and a conductor heat transfer layer (13A) that are arranged in the same plane and are separated from each other. Further, a conductor layer (11W) is also formed on an S surface (11S) that is a back surface of the core substrate 11. The conductor layer (11W) also includes a conductor circuit layer (12B) and a conductor heat transfer layer (13B) that are arranged in the same plane and are separated from each other. Further, multiple first through holes 14 and multiple second through holes 16 are formed in the core substrate 11 (in FIG. 3, only one second through hole 16 is illustrated).

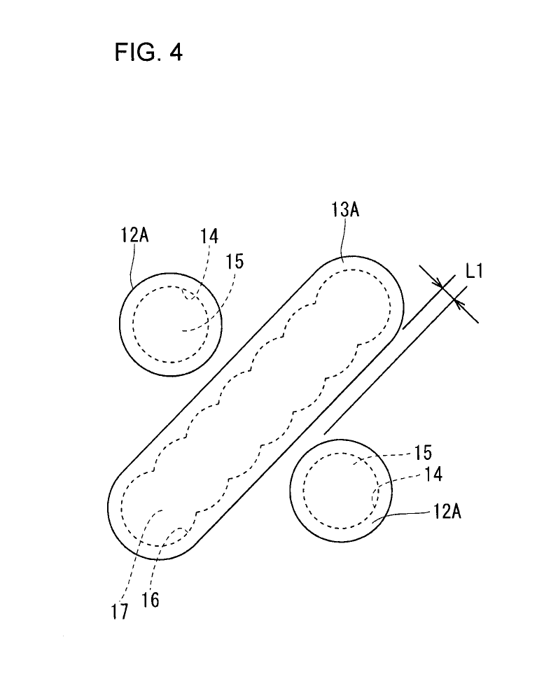

The first through holes 14 are each formed in a middle-constricted shape in which small diameter side ends of tapered holes (14A, 14B) are communicatively connected, the tapered holes (14A, 14B) being respective formed by drilling from both the F surface (11F) and the S surface (11S) of the core substrate 11 and being gradually reduced in diameter toward a deep side. In contrast, the second through holes 16 each have a structure in which multiple through holes 90 having the same shape as the first through holes 14 are arranged side by side and adjacent through holes (90, 90) are communicatively connected by being partially overlapped with each other. Specifically, the through holes 90 that each have a middle-constricted shape are arranged side by side and large diameter portions on two ends in an axial direction of adjacent through holes (90, 90) are communicatively connected; and the insulating member that forms the core substrate 11 remains between small diameter portions in the middle in the axial direction of adjacent through holes (90, 90). Further, as illustrated in FIGS. 2 and 4, the second through holes 16 each are arranged between the first through holes (14, 14) and extend in a direction that intersects a direction connecting the first through holes (14, 14).

As illustrated in FIG. 3, the first through holes 14 are filled with plating, and thereby multiple through hole electrical conductors 15 are respectively formed. The conductor circuit layer (12A) on the F surface (11F) and the conductor circuit layer (12B) on the S surface (11S) are connected by the through hole electrical conductors 15. Further, the second through holes 16 are also filled with plating, and thereby through hole thermal conductors 17 are respectively formed. The conductor heat transfer layer (13A) on the F surface (11F) and the conductor heat transfer layer (13B) on the S surface (11S) are connected by the through hole thermal conductors 17. As illustrated in FIG. 4, a distance (L1) is 15-20 μm between the conductor heat transfer layers (13A, 13B) that are connected by the through hole thermal conductors 17 (in FIG. 4, only the conductor heat transfer layer (13A) on one side is illustrated) and the conductor circuit layers (12A, 12B) that are connected by the through hole electrical conductors 15 that are respectively positioned in vicinities of both sides of the through hole thermal conductors 17 (in FIG. 4, only the conductor circuit layer (12A) on one side is illustrated).

The build-up layer (20A) on the F surface (11F) side of the core substrate 11 includes a build-up insulating layer (21A) that is laminated on the conductor layer (11V), and a build-up conductor layer (22A) that is laminated on the build-up insulating layer (21A). Further, solder resist layers (23A, 23B) are respectively laminated on the build-up conductor layers (22A, 22B).

The build-up conductor layer (22A) includes a build-up conductor circuit layer (22A1) and a build-up conductor heat transfer layer (22A2) that are arranged in the same plane and are separated from each other. Further, multiple electrical via holes (24A) and multiple thermal via holes (26A) are formed in the build-up insulating layer (21A). The electrical via holes (24A) and the thermal via holes (26A) are each formed in a tapered shape that is gradually reduced in diameter toward the core substrate 11 side.

The electrical via holes (24A) are filled with plating, and thereby multiple via electrical conductors (25A) are respectively formed. The build-up conductor circuit layer (22A1) and the conductor circuit layer (12A) are connected by the via electrical conductors (25A). Further, the thermal via holes (26A) are filled with plating, and thereby multiple via thermal conductors (27A) are respectively formed. The build-up conductor heat transfer layer (22A2) and the conductor heat transfer layer (13A) are connected by the via thermal conductors (27A).

Further, multiple pad holes are formed in the solder resist layer (23A). Portions of the build-up conductor circuit layer (22A1) are positioned inside the pad holes and become electrical pads (29A). Portions of the build-up conductor heat transfer layer (22A2) are positioned inside the pad holes and become thermal pads (31A).

The build-up layer (20B) on the S surface (11S) side of the core substrate 11 has the same layer structure as the above-described build-up layer (20A) on the F surface (11F) side. Parts of the build-up layer (20B) on the S surface (11S) in FIGS. 3 and 5A-9 are respective indicated using reference numeral symbols that are obtained by changing “A” to “B” in reference numeral symbols for corresponding parts of the build-up layer (20A) on the F surface (11F) side.

As illustrated in FIG. 2, multiple pads on an F surface (10F) (front side surface) of the circuit substrate 10 include a group of large pads that are arranged in two rows along an outer edge of the product region (R2), and a group of small pads that are arranged in multiple vertical and horizontal rows in an inner side region surrounded by the large pad group. For example, two small pads that are arranged along the diagonal line of the product region (R2) at a center of the small pad group and three small pads that are arranged at positions away from the two small pads are the thermal pads (31A), and the other small pads and the large pads are the electrical pads (29A). On the other hand, multiple pads on an S surface (10S) (back side surface) of the circuit substrate 10 are medium pads of a uniform size. Among the medium pads, those pads that are directly below or in a vicinity of directly below the thermal pads (31A) of the F surface (10F) side of the circuit substrate 10 are thermal pads (31B), and the other pads are electrical pads (29B).

The circuit substrate 10 of the present embodiment is manufactured as follows.

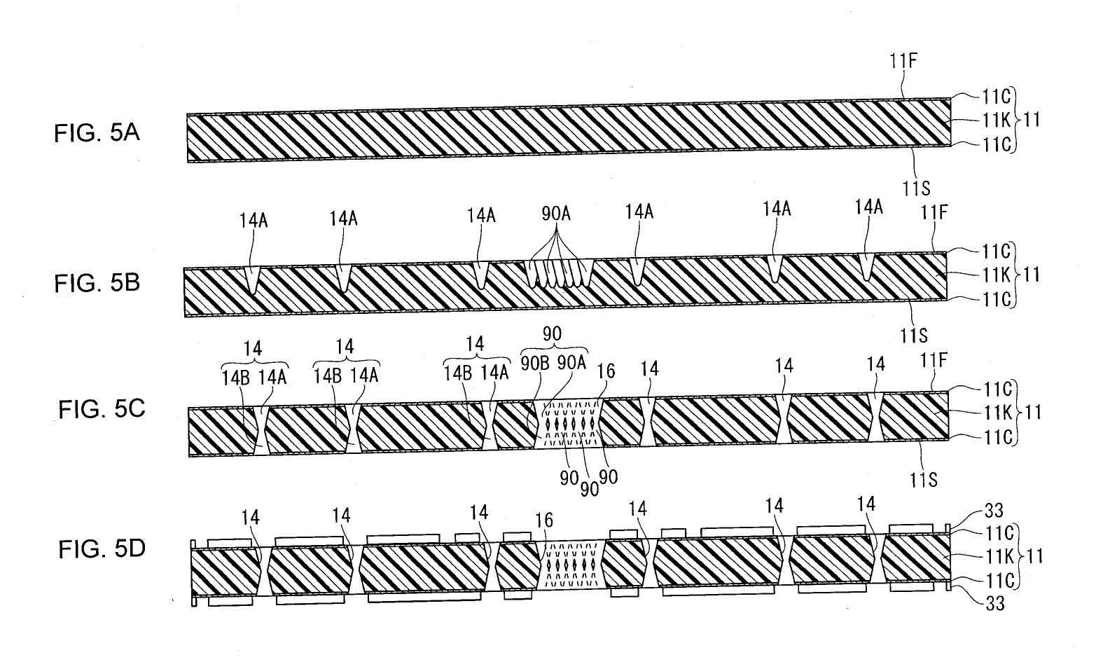

(1) As illustrated in FIG. 5A, a substrate is prepared as the core substrate 11 that is obtained by laminating a copper foil (11C) on both front and back surfaces of an insulating base material (11K) that is made of epoxy resin or BT (bismaleimide triazine) resin and a reinforcing material such as a glass cloth.

(2) As illustrated in FIG. 5B, the above-described tapered holes (14A) for forming the first through holes 14 (see FIG. 3) in the core substrate 11 are drilled by irradiating, for example, CO2 laser from the F surface (11F) side, and multiple tapered holes (90A) having the same shape as the tapered holes (14A) are drilled side by side for forming the second through holes 16 (see FIG. 3). In this case, the tapered holes (90A) are arranged such that the large diameter portions of adjacent tapered holes (90A, 90A) partially overlap each other and are communicatively connected.

(3) As illustrated in FIG. 5C, the tapered holes (14B) are drilled on the S surface (11S) side of the core substrate 11 by irradiating CO2 laser to positions directly on the back of the above-described tapered holes (14A) on the F surface (11F) side. The first through holes 14 are formed from the tapered holes (14A, 14B). Further, tapered holes (90B) having the same shape as the tapered holes (14B) are drilled on the S surface (11S) side of the core substrate 11 by irradiating CO2 laser to positions directly on the back of the above-described tapered holes (90A) on the F surface (11F) side. The through holes 90 are formed from the tapered holes (90A, 90B) and the second through holes 16 are formed from the through holes 90.

(4) An electroless plating treatment is performed, and an electroless plating film (not illustrated in the drawings) is formed on the copper foil (11C) and on inner surfaces of the first through holes 14 and the second through holes 16.

(5) As illustrated in FIG. 5D, a plating resist 33 of a predetermined pattern is formed on the electroless plating film on the copper foil (11C).

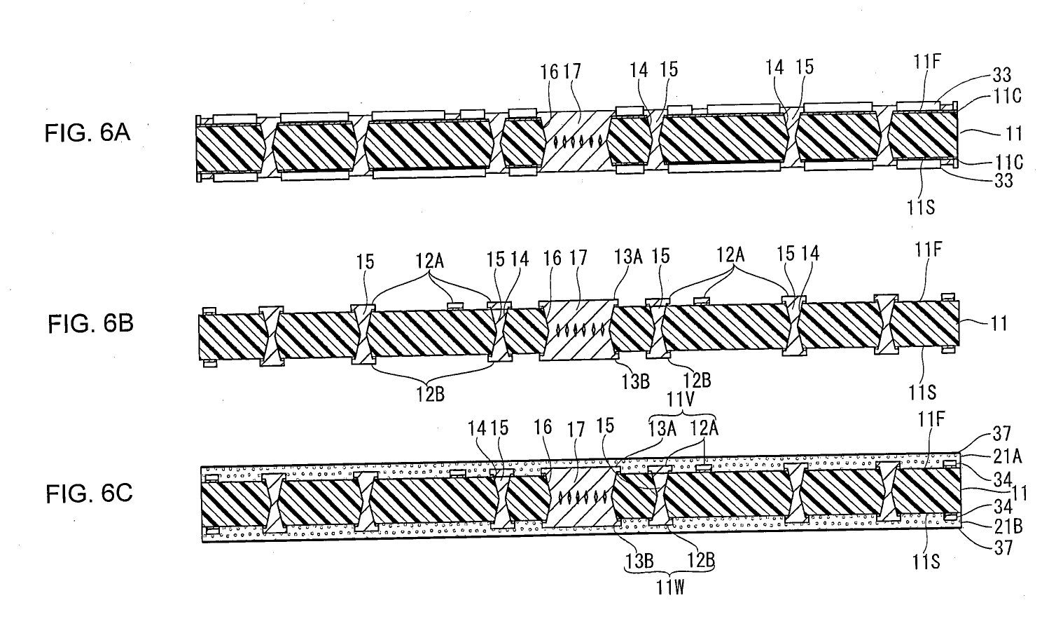

(6) As illustrated in FIG. 6A, an electrolytic plating treatment is performed. The first through holes 14 are filled with the electrolytic plating and through hole electrical conductors 15 are formed; and the second through holes 16 are filled with the electrolytic plating and through hole thermal conductors 17 are formed. Further, electrolytic plating films 34, 34 are formed on portions of the electroless plating film (not illustrated in the drawings) on the F surface (11F) and the S surface (11S) of the core substrate 11, the portions being exposed from the plating resist 33.

(7) The plating resist 33 is peeled off, and the electroless plating film (not illustrated in the drawings) and the copper foil (11C) below the plating resist 33 are removed. As illustrated in FIG. 6B, by the remaining electrolytic plating film 34, electroless plating film and copper foil (11C), the conductor circuit layer (12A) and the conductor heat transfer layer (13A) are formed on the F surface (11F) of the core substrate 11, and the conductor circuit layer (12B) and the conductor heat transfer layer (13B) are formed on the S surface (11S) of the core substrate 11. Then, a state is achieved in which the conductor circuit layer (12A) on the F surface (11F) of the core substrate 11 and the conductor circuit layer (12B) on the S surface (11S) are connected by the through hole electrical conductors 15, and the conductor heat transfer layer (13A) on the F surface (11F) of the core substrate 11 and the conductor heat transfer layer (13B) on the S surface (11S) are connected by the through hole thermal conductors 17.

(8) As illustrated in FIG. 6C, a prepreg (a resin sheet of a B-stage formed by impregnating a core material with resin) as the build-up insulating layer (21A) and a copper foil 37 are laminated on the conductor layer (11V) that includes the conductor circuit layer (12A) and the conductor heat transfer layer (13A) on the F surface (11F) of the core substrate 11, and a prepreg as the build-up insulating layer (21B) and a copper foil 37 are laminated on the conductor layer (11W) that includes the conductor circuit layer (12B) and the conductor heat transfer layer (13B) on the S surface (11S) of the core substrate 11. Then, the resulting substrate is hot-pressed. In this case, gaps between the conductor circuit layers (12A, 12A) on the F surface (11F) side of the core substrate 11 and between the conductor circuit layer (12A) and the conductor heat transfer layer (13A) are filled with the prepreg. On the S surface (11S) side of the core substrate 11, similarly, gaps between the conductor circuit layers (12B, 12B) and between the conductor circuit layer (12B) and the conductor heat transfer layer (13B) are filled with the prepreg. Instead of the prepregs, it is also possible to use resin films that do not contain a core material as the build-up insulating layers (21A, 21B). In this case, without laminating a copper foil, conductor circuit layers can be directly formed on the resin films using a semi-additive method.

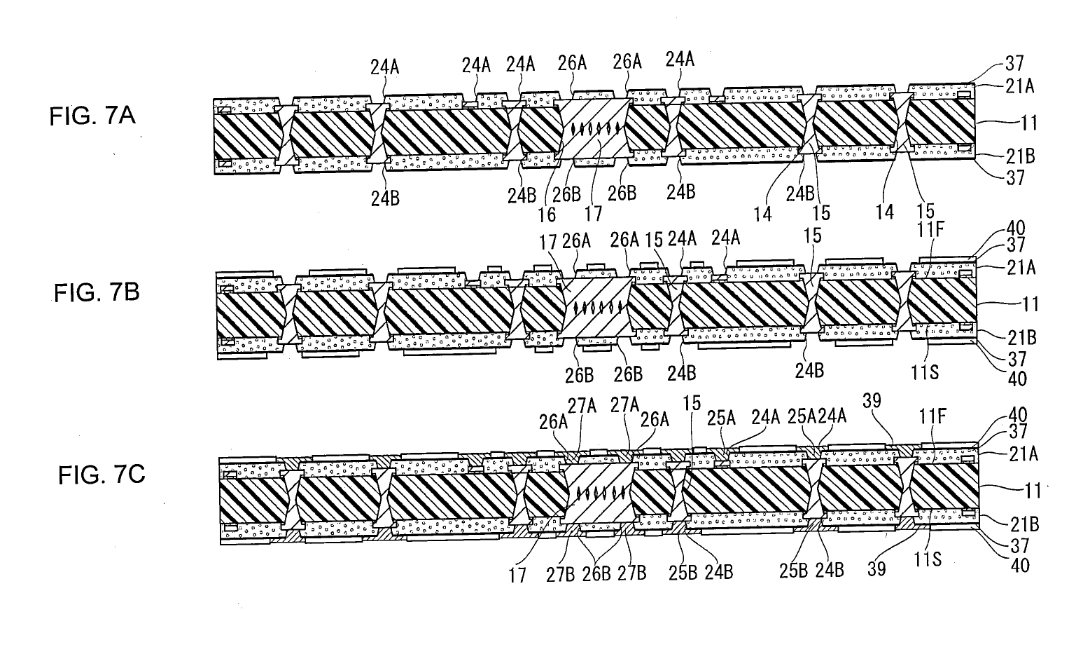

(9) As illustrated in FIG. 7A, CO2 laser is irradiated to the copper foil 37 on the F surface (11F) side of the core substrate 11 and the tapered electrical via holes (24A) and thermal via holes (26A)) are formed, penetrating through the copper foil 37 and the build-up insulating layer (21A; and CO2 laser is irradiated to the copper foil 37 on the S surface (11S) side of the core substrate 11 and the tapered electrical via holes (24B) and thermal via holes (26B) are formed, penetrating through the copper foil 37 and the build-up insulating layer (21B). Then, insides of the electrical via holes (24A, 24B) and insides of the thermal via holes (26A, 26B) are cleaned using an oxidation agent such as permanganate.

(10) An electroless plating treatment is performed, and electroless plating films (not illustrated in the drawings) are formed on the front and back copper foils 37, 37 of the core substrate 11 and on inner surfaces of the electrical via holes (24A, 24B) and the thermal via holes (26A, 26B).

(11) As illustrated in FIG. 7B, plating resists 40 of predetermined patterns are formed on the electroless plating films on the copper foils 37.

(12) An electrolytic plating treatment is performed. As illustrated in FIG. 7C, the electrical via holes (24A, 24B) are filled with the electrolytic plating and the via electrical conductors (25A, 25B) are formed; and the thermal via holes (26A, 26B) are filled with the electrolytic plating and the via thermal conductors (27A, 27B) are formed. Further, electrolytic plating films 39, 39 are formed on portions of the electroless plating film (not illustrated in the drawings) on the F surface (11F) and the S surface (11S) of the core substrate 11, the portions being exposed from the plating resist 40.

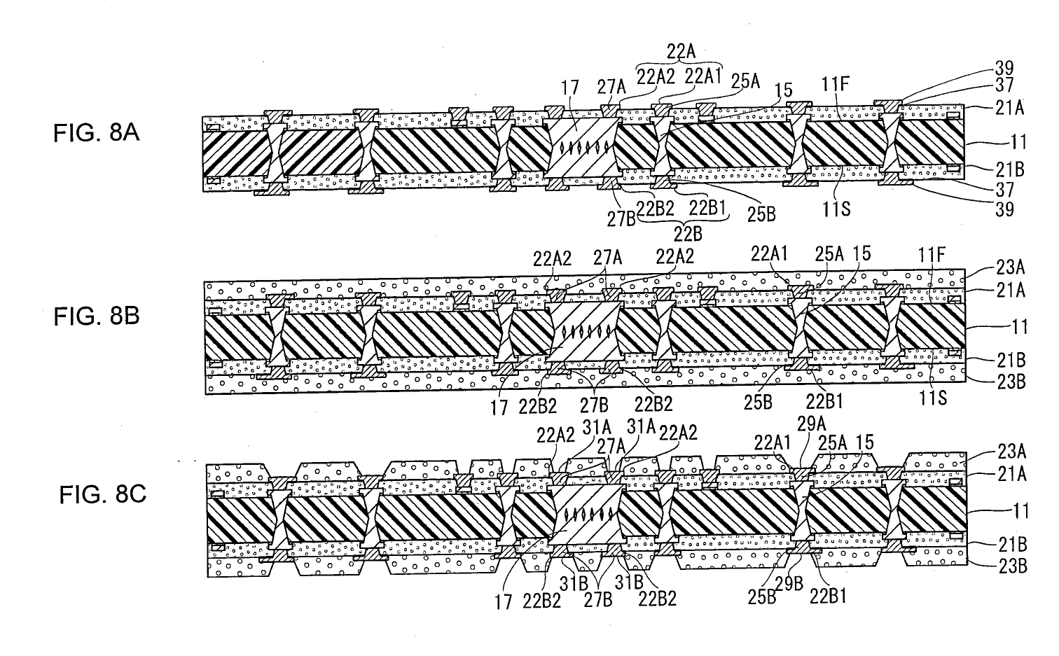

(13) The plating resist 40 is removed using 5% NaOH, and the electroless plating film (not illustrated in the drawings) and the copper foil 37 below the plating resist 40 are removed. As illustrated in FIG. 8A, by the remaining electrolytic plating film 39, electroless plating film and copper foil 37, the build-up conductor layer (22A) that includes the build-up conductor circuit layer (22A1) and the build-up conductor heat transfer layer (22A2) is formed on the F surface (11F) side of the core substrate 11, and the build-up conductor (22B) that includes a build-up conductor circuit layer (22B1) and a build-up conductor heat transfer layer (22B2) is formed on the S surface (11S) side of the core substrate 11. Then, a state is achieved in which the build-up conductor circuit layers (22A1, 22B1) and the conductor circuit layers (12A, 12B) are connected by the via electrical conductors (25A, 25B); and the build-up conductor heat transfer layers (22A2, 22B2) and the conductor heat transfer layers (13A, 13B) are connected by the via thermal conductors (27A, 27B).

(14) As illustrated in FIG. 8B, the solder resist layers (23A, 23B) are laminated on the build-up conductor layers (22A, 22B).

(15) As illustrated in FIG. 8C, tapered pad holes are formed at predetermined places of the solder resist layers (23A, 23B) and portions of the build-up conductor circuit layers (22A1, 22B1) of the build-up conductor layers (22A, 22B) are exposed from the solder resist layers (23A, 23B) to become the above-described electrical pads (29A, 29B); and portions of the build-up conductor heat transfer layers (22A2, 22B2) of the build-up conductor layers (22A, 22B) are exposed from the solder resist layers (23A, 23B) to become the above-described thermal pads (31A, 31B).

(15) As illustrated in FIG. 3, metal films 41 are formed by sequentially laminating a nickel layer and a gold layer on the electrical pads (29A, 29B) and on the thermal pads (31A, 31B). As a result, the circuit substrate 10 is completed.

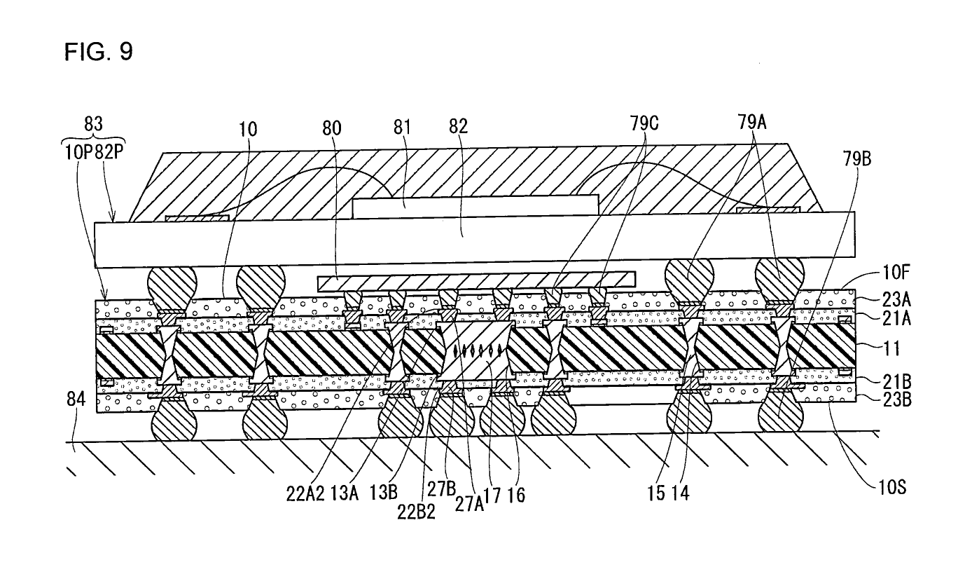

The description about the structure and the manufacturing method of the circuit substrate 10 of the present embodiment is as given above. Next, operation effects of the circuit substrate 10 are described together with an example of use of the circuit substrate 10. The circuit substrate 10 of the present embodiment is used, for example, as follows. That is, as illustrated in FIG. 9, large, medium and small solder bumps (79A, 79B, 79C) that respectively match the sizes of the above-described large, medium and small pads of the circuit substrate 10 are formed on the large, medium and small pads. Then, for example, a CPU 80 having on a lower surface a pad group that is similarly arranged as the small pad group on the F surface (10F) of the circuit substrate 10 is mounted on and soldered to the group of the small solder bumps (79C) of each product region (R2), and a first package substrate (10P) is formed. In this case, for example, grounding pads of the CPU 80 are soldered to the thermal pads (31A) of the circuit substrate 10.

Next, a second package substrate (82P) that is obtained by mounting a memory 81 on an F surface (82F) of a circuit substrate 82 is arranged from an upper side of the CPU 80 on the first package substrate (10P). The large solder bumps (79A) of the circuit substrate 10 of the first package substrate (10P) are soldered to pads (not illustrated in FIG. 9) that are provided on an S surface (82S) of the circuit substrate 82 of the second package substrate (82P). Thereby, a PoP 83 (Package on Package 83) is formed. Gaps between the circuit substrates 10, 82 in the PoP 83 are filled with resin (not illustrated in FIG. 9).

Next, the PoP 83 is arranged on a motherboard 84. The medium solder bumps (79B) on the circuit substrate 10 of the PoP 83 are soldered to a pad group of the motherboard 84. In this case, for example, grounding pads of the motherboard 84 are soldered to the thermal pads (31B) of the circuit substrate 10. When the CPU 80 and the motherboard 84 have pads dedicated to heat dissipation, the pads dedicated to heat dissipation and the thermal pads (31A, 31B) of the circuit substrate 10 may be soldered to each other.

When the CPU 80 is operating and heat is, generated, the heat is dissipated to the motherboard 84 on an opposite side of the circuit substrate 10 via the build-up conductor heat transfer layers (22A2, 22B2), the via thermal conductors (27A, 27B), the conductor heat transfer layers (13A, 13B) (on the core substrate 11) and the through hole thermal conductors 17 of the circuit substrate 10 on which the CPU 80 is mounted.

Here, the through hole thermal conductors 17 of the circuit substrate 10 are formed by filling the second through holes 16 that penetrate through the core substrate 11 with plating, and thus can be formed in the same plating process together with the through hole electrical conductors 15 that connect the front and back conductor circuit layers (12A, 12B) of the core substrate 11. Further, the second through holes 16 in which the through hole thermal conductors 17 are formed are each arranged between the first through holes 14, 14 in which the through hole electrical conductors 15 are formed and are each formed in a shape extending in a direction that intersects a direction connecting the first through holes (14, 14). Thereby, empty spaces between the through hole electrical conductors (15, 15) can be effectively utilized to form larger through hole thermal conductors 17, and efficient heat dissipation becomes possible.

Further, the second through holes 16 (in which the through hole thermal conductors 17 are formed) each have a structure in which the through holes 90 having the same shape as the first through holes 14 (in which the through hole electrical conductors 15 are formed) are arranged side by side and adjacent through holes 90 are communicatively connected by being partially overlapped with each other. Therefore, the first through holes 14 and the second through holes 16 can be formed in the same process. In addition, the first through holes 14 each have a middle-constricted shape, and the second through holes 16 are each formed by arranging side by side the through holes 90 that each have a middle-constricted shape. Therefore, filling with plating can be easily performed. Further, the second through holes 16 each have a structure in which the through holes 90 that each have a middle-constricted shape are arranged side by side, the large diameter portions of adjacent through holes 90 are communicatively connected, and the insulating material that forms the core substrate 11 remains between the small diameter portions the adjacent through holes 90. Therefore, filling with plating can be easily performed, and a contact area between the through hole thermal conductors 17 (that are formed by the plating in the second through holes 16) and the core substrate 11 is widened, and heat of the core substrate 11 can be efficiently dissipated to the through hole thermal conductors 17.

### Second Embodiment

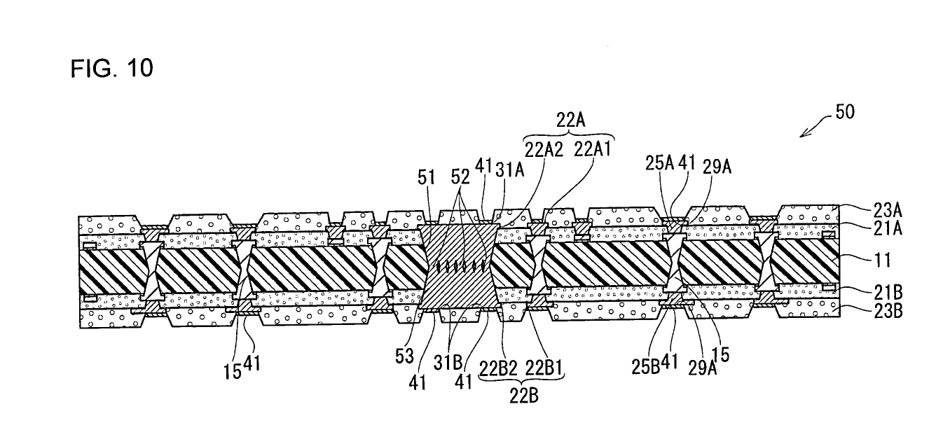

The present embodiment is illustrated in FIG. 10-12B. As illustrated in FIG. 10, only a structure of a heat transfer part such as a through hole thermal conductor 53 of a circuit substrate 50 of the present embodiment is different from that of the circuit substrate 10 of the first embodiment. In the following, regarding the circuit substrate 50 of the present embodiment, a structure that is the same as in the circuit substrate 10 of the first embodiment is indicated using the same reference numeral symbol as in the first embodiment and overlapping description is omitted, and only structures that are different from those in the circuit substrate 10 of the first embodiment are described.

The circuit substrate 50 has thermal through holes 51 that penetrate through the core substrate 11 and both the front and back build-up insulating layers (21A, 21B). Similar to the above-described second through holes 16 of the circuit substrate 10 of the first embodiment, the thermal through holes 51 each have a structure in which multiple through holes 52 that each have a middle-constricted shape are arranged side by side and large end side portions of adjacent through holes (52, 52) are mutually communicatively connected. Further, the thermal through holes 51 are filled with plating and through hole thermal conductors 53 are formed. Then, a structure is obtained in which the build-up conductor heat transfer layers (22A2, 22B2) on the front and back build-up insulating layers (21A, 21B) of the core substrate 11 are connected by the through hole thermal conductors 53. Further, the thermal through holes 51 each are arranged between the first through holes (14, 14) (in which the through hole electrical conductors 15 are formed) and extend in a direction that intersects a direction connecting the first through holes (14, 14).

The circuit substrate 50 is manufactured as follows.

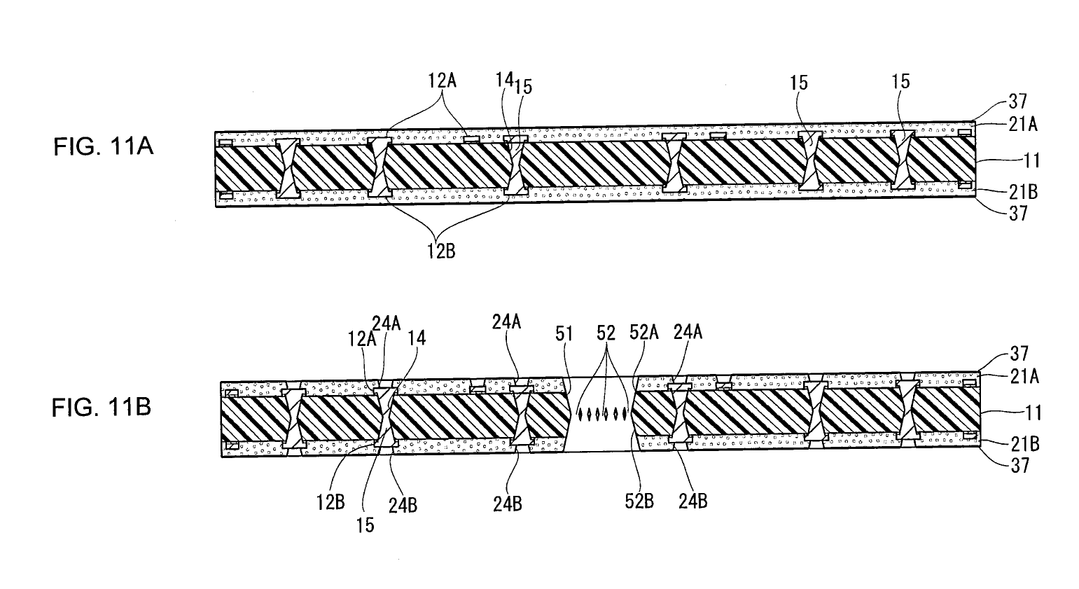

(1) Except that the above-described second through holes 16 (see FIG. 5C) of the first embodiment are not formed in the core substrate 11, by the same processes as described above, as illustrated in FIG. 11A, the first through holes 14, the through hole electrical conductors 15 and the conductor circuit layers (12A, 12B) are formed on the core substrate 11, and the prepregs as the build-up insulating layers (21A, 21B) and the copper foils 37 are laminated from upper sides of the conductor circuit layers (12A, 12B) on the F surface (11F) and on the S surface (11S) of the core substrate 11.

(2) As illustrated in FIG. 11B, by irradiating CO2 laser to the copper foil 37 on the F surface (11F) side of the core substrate 11, the tapered electrical via holes (24A) that penetrate through the copper foil 37 and the build-up insulating layer (21A) are formed, and tapered holes (52A) are formed each having a depth reaching a center in a thickness direction of the copper foil 37, the build-up insulating layer (21A) and the core substrate 11. Next, by irradiating CO2 laser to the copper foil 37 on the S surface (11S) side of the core substrate 11, the tapered electrical via holes (24B) that penetrate through the copper foil 37 and the build-up insulating layer (21B) are formed, and tapered holes (52B) are formed each having a depth reaching the center in the thickness direction of the copper foil 37, the build-up insulating layer (21B) and the core substrate 11. Then, the tapered holes (52A, 52B) on both sides of the core substrate 11 are communicatively connected and the through holes 52 that each have a middle-constricted shape are formed. The thermal through holes 51 are each formed by communicatively connecting the through holes 52.

(3) An electroless plating treatment is performed, and electroless plating films (not illustrated in the drawings) are formed on the front and back copper foils (37, 37) of the core substrate 11 and on inner surfaces of the electrical via holes (24A, 24B) and the thermal through holes 51.

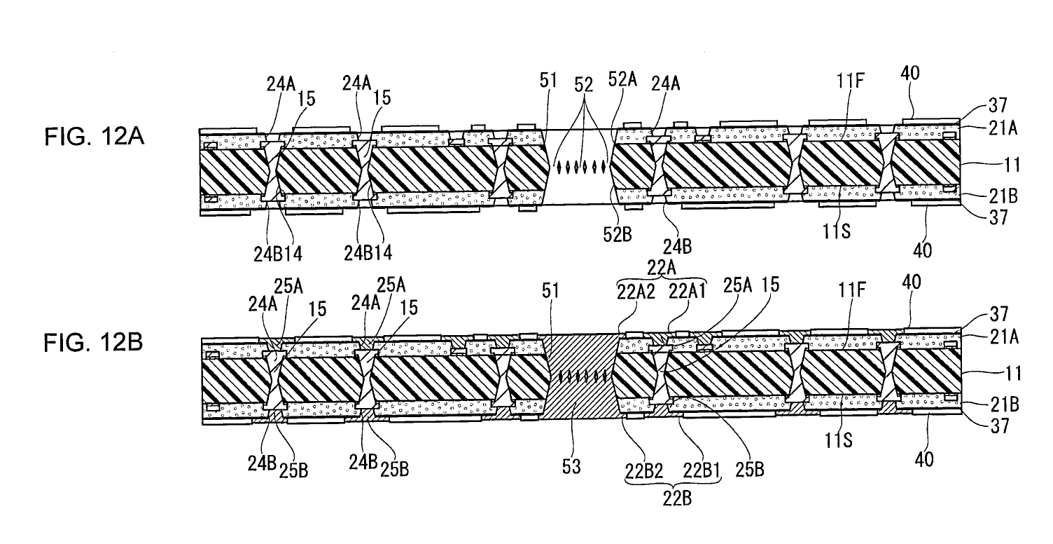

(4) As illustrated in FIG. 12A, plating resists 40 of predetermined patterns are formed on the electroless plating films on the copper foils 37.

(5) An electrolytic plating treatment is performed. As illustrated in FIG. 12B, the electrical via holes (24A, 24B) are filled with the electrolytic plating and the via electrical conductors (25A, 25B) are formed; and the thermal through holes 51 are filled with the electrolytic plating and the through hole thermal conductors 53 are formed. Further, electrolytic plating films (39, 39) are formed on portions of the electroless plating films (not illustrated in the drawings) on the F surface (11F) and the S surface (11S) of the core substrate 11, the portions being exposed from the plating resist 40.

(6) The plating resist 40 is removed, and the electroless plating film (not illustrated in the drawings) and the copper foil 37 below the plating resist 40 are removed. By the remaining electrolytic plating film 39, electroless plating film and copper foil 37, the build-up conductor layer (22A) that includes the build-up conductor circuit layer (22A1) and the build-up conductor heat transfer layer (22A2) is formed on the F surface (11F) side of the core substrate 11 (see FIG. 10). Similarly, the build-up conductor (22B) that includes the build-up conductor circuit layer (22B1) and the build-up conductor heat transfer layer (22B2) is also formed on the S surface (11S) side of the core substrate 11 (see FIG. 10).

(7) As illustrated in FIG. 10, the solder resist layers (23A, 23B) are laminated on the build-up conductor layers (22A, 22B). Then, tapered pad holes are formed at predetermined places of the solder resist layers (23A, 23B) and portions of the build-up conductor circuit layers (22A1, 22B1) of the build-up conductor layers (22A, 22B) are exposed from the solder resist layers (23A, 23B) to become the above-described electrical pads (29A, 29B); and portions of the build-up conductor heat transfer layers (22A2, 22B2) of the build-up conductor layers (22A, 22B) are exposed from the solder resist layers (23A, 23B) to become the above-described thermal pads (31A, 31B).

(8) The metal films 41 are formed by sequentially laminating a nickel layer and a gold layer on the electrical pads (29A, 29B) and on the thermal pads (31A, 31B). As a result, the circuit substrate 50 is completed.

In the circuit substrate 50 of the present embodiment, similar to the circuit substrate 10 of the first embodiment, for example, heat of a mounted CPU 80 can be dissipated to an opposite side of the circuit substrate 50 via the build-up conductor heat transfer layers (22A2, 22B2) and the through hole thermal conductors 53. The through hole thermal conductors 53 are formed by filling the thermal through holes 51 that penetrate through the core substrate 11 and the build-up insulating layers (21A, 21B) with plating, and thus can be formed in the same plating process in which the electrical via holes (24A, 24B) are filled with plating. Further, the thermal through holes 51 are each arranged between the first through holes (14, 14) in which the through hole electrical conductors 15 are formed and are each formed in a shape extending in a direction that intersects a direction connecting the first through holes (14, 14). Thereby, empty spaces between the through hole electrical conductors (15, 15) can be effectively utilized to form larger through hole thermal conductors 53, and efficient heat dissipation becomes possible.

### Other Embodiments

The present invention is not limited to the above-described embodiments. For example, embodiments described below are also included in the technical scope of the present invention. Further, in addition to the embodiments described below, the present invention can also be embodied in various modified forms within the scope without departing from the spirit of the present invention.

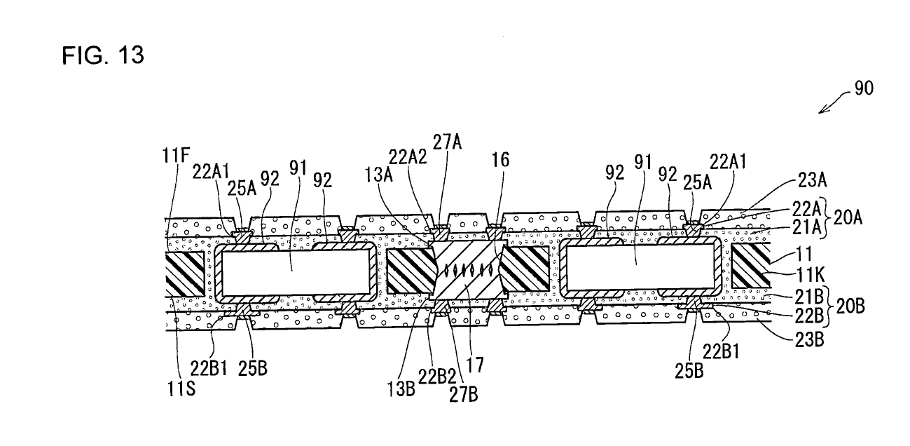

(1) The circuit substrate 10 of the first embodiment and the circuit substrate 50 of the second embodiment are used for heat dissipation of the CPU 80 that is mounted on the circuit substrates. However, a circuit substrate to which the present invention is applied may also be used for heat dissipation of other electronic components. For example, as in a circuit substrate 90 illustrated in FIG. 13, electronic components 91 are built in the insulating base material (11K) of the core substrate 11, and the through hole thermal conductor 17 can be arranged near the electronic components 91. Electrodes (92, 92) are respectively provided on two ends of each electronic component 91 in a direction parallel to the substrate. Each of the electrodes (92, 92) is connected by the via electrical conductors (25A, 25B) to the build-up conductor circuit layers (22A1, 22B1). Then, heat generated by the electronic components 91 can be dissipated by the through hole thermal conductors 17. Here, it is preferable that the through hole thermal conductors 17 each be formed at a position 70-200 μm away from the electronic components 91. By doing so, insulation with respect to the electronic components 91 can be ensured and sufficient heat dissipation effect can be expected with respect to the heat dissipation of the electronic components 91. Types of the electronic components 91 are arbitrary. Any electronic components, for example, passive components such as capacitors, resistors and coils, active components such as IC circuits, and the like, can be adopted.

(2) The second through holes 16 of the first embodiment and the thermal through holes 51 of the second embodiment are formed using laser. However, the second through holes 16 and the thermal through holes 51 may also be formed in long-hole shapes using a rotating tool.

(3) When the second through holes 16 of the first embodiment and the thermal through holes 51 of the second embodiment are formed, a portion of the core substrate 11 remains between the small diameter portions of the middle-constricted through holes that form each of the second through holes 16 and each of the thermal through holes 51. However, it is also possible that the small diameter portions of the middle-constricted through holes are also communicatively connected.

(4) In the circuit substrate 10 of the first embodiment, the build-up layers (20A, 20B) are laminated on the core substrate 11. However, the present invention may also be applied to a circuit substrate that does not have a build-up layer.

In a conventional circuit substrate, there are problems such as that the thermal conductor greatly inhibits densification of circuits, for example, the thermal conductor cannot be arranged directly below a semiconductor chip that has a densified connecting part with the circuit substrate, and that the thermal conductor hinders miniaturization of the circuit substrate. Further, there is a problem that, when the circuit substrate is manufactured, a process is added for embedding the thermal conductor in the insulating layer.

A circuit substrate according to an embodiment of the present invention suppresses inhibition of circuit densification due to a thermal conductor, and an embodiment of the present invention is a method for manufacturing such a circuit substrate.

A circuit substrate according to one aspect of the invention includes: an insulating layer; conductor circuit layers that are respectively formed on both front and back surfaces of the insulating layer; multiple through hole electrical conductors that are formed by filling multiple first through holes that penetrate through the insulating layer with plating, and connect the conductor circuit layers on the front and back surfaces of the insulating layer; conductor heat transfer layers that are respectively formed on both the front and back surfaces of the insulating layer, and are respectively arranged in the same plane as the conductor circuit layers; and a through hole thermal conductor that is formed by filling a second through hole that penetrates through the insulating layer with plating, and connects the conductor heat transfer layers on the front and back surfaces of the insulating layer. The second through hole is arranged between at least two of the first through holes, and is formed in a shape extending in a direction that intersects a direction connecting the first through holes.

Obviously, numerous modifications and variations of the present invention are possible in light of the above teachings. It is therefore to be understood that within the scope of the appended claims, the invention may be practiced otherwise than as specifically described herein.

What is claimed is:

1. A circuit substrate, comprising:
an insulating layer;
a plurality of conductor circuit layers including a first conductor circuit layer formed on a first surface side of the insulating layer and a second conductor circuit layer formed on a second surface side of the insulating layer;
a plurality of conductor heat transfer layers including a first conductor heat transfer layer formed on the first surface side of the insulating layer and a second conductor heat transfer layer formed on the second surface side of the insulating layer;
a plurality of through hole electrical conductors comprising plating filling a plurality of first through holes penetrating through the insulating layer such that the plurality of through hole electrical conductors is connecting the first and second conductor circuit layers; and
a through hole thermal conductor comprising plating filling a second through hole penetrating through the insulating layer such that the through hole thermal conductor is connecting the first and second conductor heat transfer layers,
wherein the second through hole is positioned between at least two of the first through holes and has a shape extending in a direction that intersects a direction connecting the at least two of the first through holes.

2. A circuit substrate according to claim 1, wherein the first conductor circuit layer and the first conductor heat transfer layer are formed on a first surface of the insulating layer such that a first conductor layer formed on the first surface of the insulating layer includes the first conductor circuit layer and the first conductor heat transfer layer, and the second conductor circuit layer and the second conductor heat transfer layer are formed on a second surface of the insulating layer such that a second conductor layer formed on the second surface of the insulating layer includes the second conductor circuit layer and the second conductor heat transfer layer.

3. A circuit substrate according to claim 2, wherein the second through hole comprises a plurality of through holes formed side-by side such that adjacent through holes are overlapping each other, and each of the through holes has a shape which is same as a shape of each of the first through holes.

4. A circuit substrate according to claim 3, wherein the shape of each of the first through holes comprises a plurality of tapered holes connected such that a connected portion of the tapered holes has a smallest diameter in the shape.

5. A circuit substrate according to claim 4, wherein the second through hole comprises the plurality of through holes formed side-by side such that large diameter portions of the adjacent through holes are overlapping each other and that connected portions of the adjacent through holes are separated by the insulating layer.

6. A circuit substrate according to claim 2, further comprising:
a first build-up layer formed on the first surface of the insulating layer and comprising a build-up insulating layer, a build-up conductor layer, a build-up conductor heat transfer layer, a via conductor and a via heat transfer conductor such that the via conductor is formed in the build-up insulating layer and connecting the build-up conductor layer and the first conductor circuit layer and that the via heat transfer conductor is formed in the build-up insulating layer and connecting the build-up conductor heat transfer layer and the first conductor heat transfer layer; and
a second build-up layer formed on the second surface of the insulating layer and comprising a build-up insulating layer, a build-up conductor layer, a build-up conductor heat transfer layer, a via conductor and a via heat transfer conductor such that the via conductor is formed in the build-up insulating layer and connecting the build-up conductor layer and the second conductor circuit layer and that the via heat transfer conductor is formed in the build-up insulating layer and connecting the build-up conductor heat transfer layer and the second conductor heat transfer layer,
wherein the insulating layer is forming a core substrate, the via conductor and the via heat transfer conductor in the first build-up layer comprise plating filling via holes formed in the build-up insulating layer in the first build-up layer, and the via conductor and the via heat transfer conductor in the second build-up layer comprise plating filling via holes formed in the build-up insulating layer in the second build-up layer.

7. A circuit substrate according to claim 2, further comprising:
an electronic component accommodated in the insulating layer such that the through hole thermal conductor is positioned adjacent to the electronic component.

8. A circuit substrate according to claim 3, further comprising:
a first build-up layer formed on the first surface of the insulating layer and comprising a build-up insulating layer, a build-up conductor layer, a build-up conductor heat transfer layer, a via conductor and a via heat transfer conductor such that the via conductor is formed in the build-up insulating layer and connecting the build-up conductor layer and the first conductor circuit layer and that the via heat transfer conductor is formed in the build-up insulating layer and connecting the build-up conductor heat transfer layer and the first conductor heat transfer layer; and
a second build-up layer formed on the second surface of the insulating layer and comprising a build-up insulating layer, a build-up conductor layer, a build-up conductor heat transfer layer, a via conductor and a via heat transfer conductor such that the via conductor is formed in the build-up insulating layer and connecting the build-up conductor layer and the second conductor circuit layer and that the via heat transfer conductor is formed in the build-up insulating layer and connecting the build-up conductor heat transfer layer and the second conductor heat transfer layer,
wherein the insulating layer is forming a core substrate, the via conductor and the via heat transfer conductor in the first build-up layer comprise plating filling via holes formed in the build-up insulating layer in the first build-up layer, and the via conductor and the via heat transfer conductor in the second build-up layer comprise plating filling via holes formed in the build-up insulating layer in the second build-up layer.

9. A circuit substrate according to claim 4, further comprising:
a first build-up layer formed on the first surface of the insulating layer and comprising a build-up insulating layer, a build-up conductor layer, a build-up conductor heat transfer layer, a via conductor and a via heat transfer conductor such that the via conductor is formed in the build-up insulating layer and connecting the build-up conductor layer and the first conductor circuit layer and that the via heat transfer conductor is formed in the build-up insulating layer and connecting the build-up conductor heat transfer layer and the first conductor heat transfer layer; and
a second build-up layer formed on the second surface of the insulating layer and comprising a build-up insulating layer, a build-up conductor layer, a build-up conductor heat transfer layer, a via conductor and a via heat transfer conductor such that the via conductor is formed in the build-up insulating layer and connecting the build-up conductor layer and the second conductor circuit layer and that the via heat transfer conductor is formed in the build-up insulating layer and connecting the build-up conductor heat transfer layer and the second conductor heat transfer layer,
wherein the insulating layer is forming a core substrate, the via conductor and the via heat transfer conductor in the first build-up layer comprise plating filling via holes formed in the build-up insulating layer in the first build-up layer, and the via conductor and the via heat transfer conductor in the second build-up layer comprise plating filling via holes formed in the build-up insulating layer in the second build-up layer.

10. A circuit substrate according to claim 5, further comprising:
a first build-up layer formed on the first surface of the insulating layer and comprising a build-up insulating layer, a build-up conductor layer, a build-up conductor heat transfer layer, a via conductor and a via heat transfer conductor such that the via conductor is formed in the build-up insulating layer and connecting the build-up conductor layer and the first conductor circuit layer and that the via heat transfer conductor is formed in the build-up insulating layer and connecting the build-up conductor heat transfer layer and the first conductor heat transfer layer; and
a second build-up layer formed on the second surface of the insulating layer and comprising a build-up insulating layer, a build-up conductor layer, a build-up conductor heat transfer layer, a via conductor and a via heat transfer conductor such that the via conductor is formed in the build-up insulating layer and connecting the build-up conductor layer and the second conductor circuit layer and that the via heat transfer conductor is formed in the build-up insulating layer and connecting the build-up conductor heat transfer layer and the second conductor heat transfer layer,
wherein the insulating layer is forming a core substrate, the via conductor and the via heat transfer conductor in the first build-up layer comprise plating filling via holes formed in the build-up insulating layer in the first build-up layer, and the via conductor and the via heat transfer conductor in the second build-up layer comprise plating filling via holes formed in the build-up insulating layer in the second build-up layer.

11. A circuit substrate according to claim 2, further comprising:
a first build-up layer formed on a first surface of the insulating layer and comprising a build-up insulating layer, a build-up conductor layer and a plurality of via conductors such that the plurality of via conductors is formed in the build-up insulating layer and connecting the build-up conductor layer; and
a second build-up layer formed on a second surface of the insulating layer and comprising a build-up insulating layer, a build-up conductor layer and a plurality of via conductors such that the plurality of via conductors is formed in the build-up insulating layer and connecting the build-up conductor layer and the second conductor circuit layer,
wherein the insulating layer is forming a core substrate, the first conductor heat transfer layer is formed on the build-up insulating layer on the first surface side of the insulating layer, the second conductor heat transfer layer is formed on the build-up insulating layer on the second surface side of the insulating layer, the through hole thermal conductor comprises the plating filling the second through hole penetrating through the insulating layer and the build-up insulating layers on the first and second surface sides of the insulating layer such that the through hole thermal conductor is connecting the first and second conductor heat transfer layers, the via conductors in the first build-up layer comprise plating filling via holes formed in the build-up insulating layer in the first build-up layer, the via conductors in the second build-up layer comprise plating filling via holes formed in the build-up insulating layer in the second build-up layer, and the second through hole is positioned between at least two of the via conductors in each of the first and second build-up layers and has a shape extending in a direction that intersects a direction connecting the at least two of the via conductors in each of the first and second build-up layers.

12. A circuit substrate according to claim 11, wherein the second through hole comprises a plurality of through holes formed side-by side such that adjacent through holes are overlapping each other.

13. A circuit substrate according to claim 11, wherein each of the first through holes has a shape comprising a plurality of tapered holes connected such that a connected portion of the tapered holes has a smallest diameter in the shape.

14. A circuit substrate according to claim 12, wherein the second through hole comprises the plurality of through holes formed side-by side such that large diameter portions of the adjacent through holes are overlapping each other and that connected portions of the adjacent through holes are separated by the insulating layer.

15. A circuit substrate according to claim 11, further comprising:
an electronic component accommodated in the insulating layer such that the through hole thermal conductor is positioned adjacent to the electronic component.

16. A method for manufacturing a circuit substrate, comprising:
forming a plurality of first through holes penetrating through an insulating layer;
forming a plurality of second through hole penetrating through the insulating layer;
filling plating in the plurality of first through holes such that a plurality of through hole electrical conductors comprising the plating is formed through the insulating layer;
filing plating in the second through hole such that a through hole thermal conductor comprising the plating is formed through the insulating layer;
forming a plurality of conductor circuit layers including a first conductor circuit layer on a first surface side of the insulating layer and a second conductor circuit layer on a second surface side of the insulating layer such that the first and second conductor circuit layers are connected by the plurality of through hole electrical conductors; and
forming a plurality of conductor heat transfer layers including a first conductor heat transfer layer on the first surface side of the insulating layer and a second conductor heat transfer layer on the second surface side of the insulating layer such that the first and second conductor heat transfer layers are connected by the through hole thermal conductor,
wherein the forming of the second through hole comprises positioning the second through hole between at least two of the first through holes and forming the second through hole in a shape extending in a direction that intersects a direction connecting the at least two of the first through holes.

17. A method for manufacturing a circuit substrate according to claim 16, wherein the first conductor circuit layer and the first conductor heat transfer layer are formed on a first surface of the insulating layer such that a first conductor layer is formed on the first surface of the insulating layer to include the first conductor circuit layer and the first conductor heat transfer layer, and the second conductor circuit layer and the second conductor heat transfer layer are formed on a second surface of the insulating layer such that a second conductor layer is formed on the second surface of the insulating layer to include the second conductor circuit layer and the second conductor heat transfer layer.

18. A method for manufacturing a circuit substrate according to claim 17, wherein the filling of the plating in the plurality of first through holes and the filing of the plating in the second through hole comprise filling the plating in the plurality of first through holes and the second through hole in a same process such that the plurality of through hole electrical conductors and the through hole thermal conductor are formed in the same process.

19. A method for manufacturing a circuit substrate according to claim 16, further comprising:
forming on a first surface of the insulating layer a first build-up layer comprising a build-up insulating layer, a build-up conductor layer and a plurality of via conductors such that the plurality of via conductors is formed in the build-up insulating layer and connecting the build-up conductor layer; and
forming on a second surface of the insulating layer a second build-up layer comprising a build-up insulating layer, a build-up conductor layer and a plurality of via conductors such that the plurality of via conductors is formed in the build-up insulating layer and connecting the build-up conductor layer and the second conductor circuit layer,
wherein the insulating layer is forming a core substrate, the forming of the plurality of conductor heat transfer layers comprises forming the first conductor heat transfer layer on the build-up insulating layer on the first surface side of the insulating layer and forming the second conductor heat transfer layer on the build-up insulating layer on the second surface side of the insulating layer, the forming of the second through hole comprises forming the second through hole penetrating through the insulating layer and the build-up insulating layers on the first and second surface sides of the insulating layer, the forming of the first build-up layer includes filling plating in via holes formed in the build-up insulating layer in the first build-up layer to form the via conductors in the first build-up layer, the forming of the second build-up layer includes filling plating in via holes formed in the build-up insulating layer in the second build-up layer to form the via conductors in the second build-up layer, and the forming of the second through hole comprises positioning the second through hole between at least two of the via conductors in each of the first and second build-up layers and forming the second through hole such that the shape of the second through hole extends in a direction that intersects a direction connecting the at least two of the via conductors in each of the first and second build-up layers.

20. A method for manufacturing a circuit substrate according to claim 19, wherein the filling of the plating in the via holes in the first build-up layer, the filling of the plating in the via holes in the second build-up layer, and the filing of the plating in the second through hole comprise filling the plating in the via holes in the first and second build-up layers and the second through hole in a same process such that the via conductors in the first and second build-up layers and the through hole thermal conductor are formed in the same process.
